(19) United States
(12) Patent Application Publication
(10) Pub. No.: US 2003/0214039 A1
(43) Pub. Date: Nov. 20, 2003

(54) Method for fabricating semiconductor device having tertiary diffusion barrier layer for copper line

(76) Inventor: Dong-Soo Yoon, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/320,403

(22) Filed: Dec. 17, 2002

(30) Foreign Application Priority Data
May 18, 2002 (KR) 2002-27605

(51) Int. Cl. H01L 21/4763; H01L 23/48; H01L 23/52; H01L 21/44; H01L 29/40

(52) U.S. Cl. 257/751; 438/627; 438/629; 438/631; 438/633; 438/643; 438/687; 438/653; 438/656

(57) ABSTRACT

The present invention relates to a method for fabricating a semiconductor device having a diffusion barrier layer with a Cu line to prevent degradation in performance of the diffusion barrier layer. The present invention provides a method for fabricating a semiconductor device, including the steps of: depositing a tertiary nitride containing Ti, W and N on a substrate loaded inside of a reactive deposition chamber; and densifying the tertiary nitride and performing a reforming process for filling a surface of the tertiary nitride with oxygen. Also, the present invention provides a method for fabricating a semiconductor device, including the steps of: forming a conductive layer on top of a substrate; forming a diffusion barrier layer constructed with titanium (Ti), tungsten (W) and nitrogen (N) on the conductive layer; and forming a Cu line on the diffusion barrier layer.

### FIELD OF THE INVENTION

The present invention relates to a method for fabricating a semiconductor device; and, more particularly, to a method for fabricating a semiconductor device having a tertiary diffusion barrier layer for a copper line.

### DESCRIPTION OF RELATED ARTS

In general, a metal line is used to electrically interconnect devices or metal lines. Although aluminum (Al) or tungsten (W) is commonly used for a metal line, this metal line is hardly applicable to a highly integrated semiconductor device due to a low melting point and high resistivity.

Also, as a degree of integration process has been highly progressed, it is also required to use a material having low resistivity and high reliability in electromigration (EM) and stressmigration (SM). It is copper (Cu) that, is currently focused for a material satisfying the above requirements.

The reason for using Cu as the metal line is because Cu has a relatively higher melting point around 1080° C., compared to Al and W of which melting points are around 660° C. and 3400° C., respectively. Also, resistivity of Cu is about 1.7 μΩcm, and this value is very lower than Al and W. Referentially, Al and W have resistivity about 2.7 μΩcm and about 5.6 μΩcm, respectively.

However, Cu has a highly diffusible within silicon and oxides, and thus, requiring a diffusion barrier layer for preventing the Cu diffusion effect.

The diffusion barrier layer uses metal or a nitride that completely dose not react with Cu. Also, performance level of the diffusion barrier layer against Cu ascends in an order of refractory metal, a secondary nitride and a tertiary nitride. For instance, Ti, TiN, WN, TiN and TiSiN can be used as the diffusion barrier layer.

Since Cu spreads out only through diffusion, it is advantageous to make a microstructure of the diffusion barrier layer amorphous so that there is no rapid diffusion path found within the microstructure.

An amorphous tertiary diffusion barrier layer is expected to have an excellent performance for preventing diffusion. Particularly, among those currently developed diffusion barrier layers, an amorphous tertiary nitride is the most excellent diffusion barrier layer. The amorphous tertiary nitride is formed with refractory metal and Si and N atoms are added to the refractory metal.

FIG. 1 is a diagram schematically illustrating a copper (Cu) line in accordance with a prior art.

Referring to FIG. 1, an inter-layer insulating layer 12 is formed on a silicon substrate 11, and then, selectively etched to form a contact hole exposing a certain portion of the silicon substrate 11. After forming the contact hole, an amorphous tertiary nitride 13, e.g., TiSiN and a Cu layer 14 are filled within the contact hole to form a Cu line.

At this time, the amorphous tertiary nitride 13 is the diffusion barrier layer preventing diffusion of Cu within the Cu layer 14.

However, since the amorphous tertiary nitride 13 includes silicon, electric resistance of a thin film increases due to coupling of Si and N. Also, there occurs another problem of degrading the performance level of the diffusion barrier layer because a strong chemical affinity between the Si and N decreases a critical temperature for changing a state of the diffusion barrier layer from amorphous to crystalline.

### SUMMARY OF THE INVENTION

It is, therefore, an object of the present invention to provide a method for fabricating a semiconductor device having a silicon containing diffusion barrier layer to prevent a performance level of the diffusion barrier layer from being degraded by copper (Cu) provided from a Cu line.

In accordance with an aspect of the present invention, there is provided a method for fabricating a semiconductor device, including the steps of: depositing a tertiary nitride containing Ti, W and N on a substrate loaded inside of a reactive deposition chamber; and densifying the tertiary nitride and performing a reforming process for filling a surface of the tertiary nitride with oxygen.

Also, the step of depositing the tertiary nitride further includes the steps of: mounting a Ti target and a W target inside of the reactive deposition chamber; supplying a mixed gas of argon (Ar) and nitrogen (N₂) gas to the reactive deposition chamber; forming Ar plasma by ionizing the Ar gas; setting Ar⁺ ions contained in the Ar plasma to collide with the Ti target and the W target; and setting Ti+ and W+ ions come off from each surface of the Ti and W targets to react with the N₂ gas.

In accordance with another aspect of the present invention, there is also provided a method for fabricating a semiconductor device, comprising the steps of: forming a conductive layer on top of a substrate; forming a diffusion barrier layer constructed with titanium (Ti), tungsten (W) and nitrogen (N) on the conductive layer; and forming a Cu line on the diffusion barrier layer.

In addition, the step of forming the diffusion barrier layer is deposited at a temperature in a range from 100° C. to about 900° C. until having a thickness ranging from about 200 Å to about 1000 Å. Furthermore, each compositional ratio of the Ti, -W and N contained in the tertiary nitride ranges from about 50 at % to about 90 at %, from about 10 at % to about 50 at %, about 10 at % to about 80 at %.

### BRIEF DESCRIPTION OF THE DRAWING(S)

The above and other objects and features of the present invention will become apparent from the following description of the preferred embodiments given in conjunction with the accompanying drawings, in which:

FIG. 1 is a diagram illustrating a method for fabricating a semiconductor device including a copper (Cu) line in accordance with a prior art;

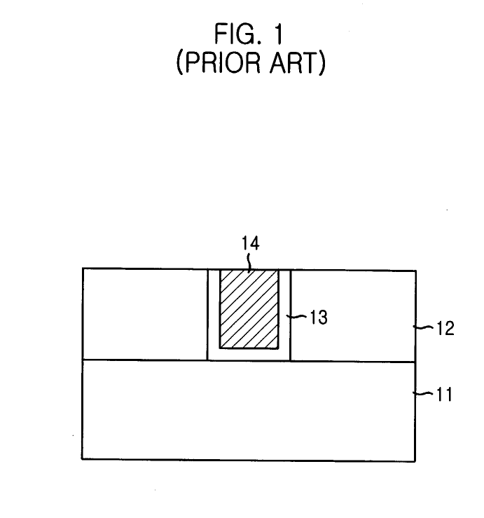

FIG. 2 is a diagram showing constitutional elements of a TiWN deposition equipment in accordance with a preferred embodiment of the present invention; and

FIGS. 3A and 3B are cross-sectional views illustrating a method for fabricating a semiconductor device including a Cu line in accordance with the preferred embodiment of the present invention.

### DETAILED DESCRIPTION OF THE INVENTION

The present invention provides a tertiary nitride diffusion barrier layer having an excellent characteristic of preventing diffusion of copper (Cu) even though silicon is not contained in the tertiary nitride diffusion barrier layer.

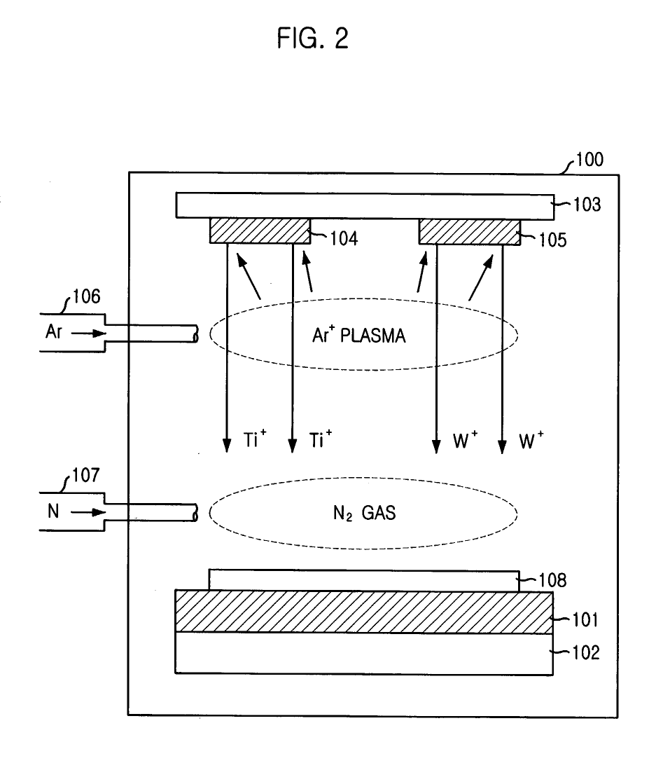

FIG. 2 is a diagram showing a physical vapor deposition (PVD) chamber for depositing a TiWN layer in accordance with a preferred embodiment of the present invention.

Referring to FIG. 2, the PVD chamber is a reactive deposition chamber 100 including a wafer 101 on which a tertiary diffusion barrier layer is deposited, a substrate supporting unit 102 for supporting the wafer 101, a titanium (Ti) target 104 and a tungsten (W) target 105, each being supported by a target supporting unit 103 allocated in a direction of facing the wafer 101, an argon (Ar) gas supplying unit 106 for supplying Ar gas to the reactive deposition chamber 100 and a nitrogen (N₂) supplying unit 107 for supplying N₂ gas to the reactive deposition chamber 100. Herein, the Ar gas is a sputter gas and the N₂ gas is a reaction gas.

Also, the Ar gas supplying unit 106 supplies such inert gas as Ar, while the N₂ gas supplying unit 107 supplies N₂ gas. Amounts and supplying duration time of the Ar and N₂ gas are controlled through a valve (not shown).

Furthermore, the wafer 101 is constructed on the substrate supporting unit 102 so for the wafer 101 to maintain uniformly a parallel distance with the Ti target 104 and the W target 105.

A TiWN deposition process is started with a step of supplying a mixed gas of Ar and N₂ gas to a space between the wafer 101 and each of the Ti and W targets 104 and 105 within the reactive deposition chamber 100. Then, the Ar gas is ionized to form Ar plasma. The Ar⁺ ions provided from the Ar plasma are accelerated and collided with the Ti and W targets 104 and 105 by using an electromagnetic field.

Atoms or molecules existing on a surface of the Ti and W targets 104 and 105 come off due to transformational energy from the collision. These Ti⁺ and W⁺ ions chemically react with the N₂ gas, which is a reaction gas, so to deposit a TiWN layer 108 on the wafer 101.

A physical vapor deposition (PVD) technique, an ionized metal plasma (IMP) technique or a collimated physical vapor deposition technique is used for the deposition of the TiWN layer.

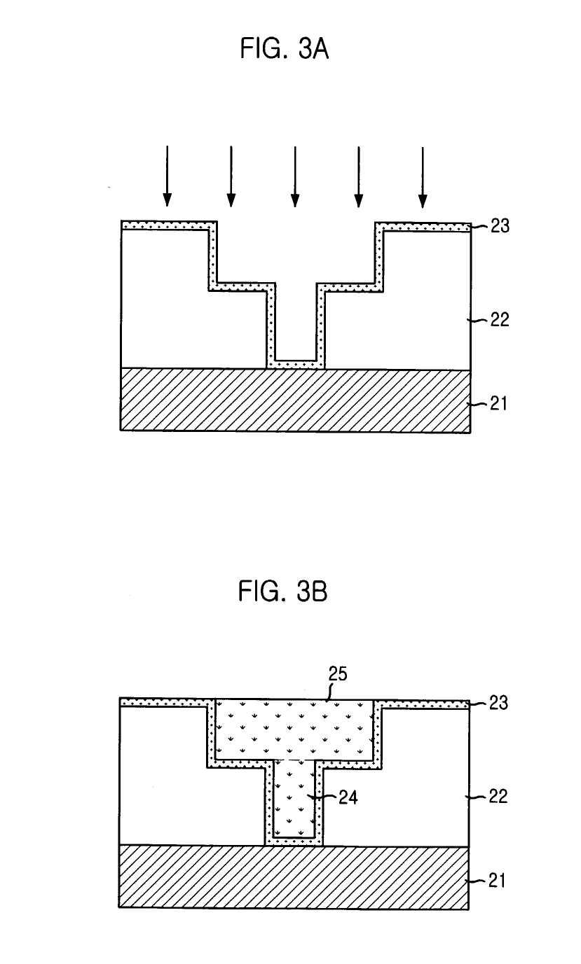

FIGS. 3A and 3B are cross-sectional views illustrating a method for fabricating a semiconductor device having a TiWN diffusion barrier layer with a Cu line in accordance with the preferred embodiment of the present invention.

Referring to FIG. 3A, an inter-layer insulating layer 22 is deposited on a substrate (not shown) providing a bottom layer 21. The inter-layer insulating layer 22 is then selectively etched through a dual damascene process so to form a dual damascene pattern, e.g., a via hole pattern and a line pattern.

Herein, the bottom layer 21 can be a conductive layer such as a metal line to which a subsequent Cu line is connected or a semiconductive substrate ion implanted with impurities.

Next, the substrate having the via hole pattern and the line pattern is loaded inside of the reactive deposition chamber, and Ar and N₂ gas are added to the reactive deposition chamber to form Ar plasma. Continuously, Ar⁺ ions contained in the Ar plasma are collided with the Ti and W targets so to make Ti and W atoms or molecules existing on each surface of the Ti and W targets come off. These Ti⁺ and W⁺ ions are reacted with the N₂ gas to deposit a TiWN 23 along the via hole pattern and the line pattern. Herein, the TiWN 23 is a diffusion barrier layer.

The TiWN 23 is deposited to a thickness ranging between about 200 Å and 1000 Å at a temperature ranging from about 100° C. to about 900° C. Each compositional ratio of Ti, W and N contained in the TiWN 23 is maintained a range of about 50˜90 at %, 10˜50 at % and 10˜80 at %, respectively.

Next, after depositing the TiWN 23, a reforming process is performed to increase density of the TiWN 23 and fill oxygen to the TiWN 23.

The densification and the oxygen filling are taken place inside of the reactive reaction chamber or an additional thermal process chamber.

The densification and the oxygen filling processes taken place inside of the additional thermal process chamber is completed by performing a series of steps as following: the TiWN 23 is transferred to the thermal process chamber after depositing the TiWN 23 and proceeded with a rapid thermal process (RTP). The RTP is carried out at a temperature ranging from about 100° C. to about 650° C. for about 1 minute to 5 minutes in an atmosphere of O₂, a mixture of Ar and O₂ or a mixture of N₂ and O₂. At this time, a flow quantity of each O₂, Ar and N₂ is changing during the RTP.

The following will describe the densification and oxygen filling processes taken place inside of the reactive deposition chamber.

As a first preferred embodiment, when depositing the TiWN 23, O₂ is added inside of the reactive deposition chamber and ionized thereafter. An electromagnetic field around the bottom layer 21 accelerates the ionized oxygen towards the TiWN 23 so as to densify the TiWN 23 as simultaneously as to fill oxygen.

As a second preferred embodiment, Ar gas is added to the reactive deposition chamber and ionized thereafter. The ionized Ar⁺ are collided with the TiWN 23 to densify the TiWN 23. Subsequently, oxygen ions are additionally added to form a uniform oxide layer on the TiWN 23.

As a third preferred embodiment, N₂ gas added to the reactive deposition chamber is ionized, and then, collided with the TiWN 23 to densify the TiWN 23. Thereafter, oxygen ions are additionally added to the reactive deposition chamber to form a uniform oxide layer on the TiWN 23.

As a forth preferred embodiment, N₂ and O₂ gas are simultaneously added to the reactive deposition chamber and ionized thereafter. The ionized N₂ are collided with the TiWN 23 to make the TiWN dense, and then, a uniform oxide layer is formed on the TiWN by using the ionized O₂.

As a fifth preferred embodiment, NH₄ is used for a thermal process performed inside of the reactive deposition technique so as to densify the TiWN 23. Then, additionally added O₂ is ionized, and the ionized O₂ is used for forming a uniform oxide layer on the TiWN 23.

As a sixth preferred embodiment of the present invention, the TiWN 23 is densified through NH₄ plasma treatment inside of the reactive deposition chamber. O₂ is then additionally added and ionized to form a uniform oxide layer on the TiWN 23.

As a seventh preferred embodiment, UV ozone is employed for a thermal process carried out inside of the reactive deposition chamber to densify the TiWN 23 as simultaneously as to form a uniform oxide layer.

By combining the above-described first to seventh preferred embodiments, it is also possible to change properties of the TiWN 23 through a reforming process. Furthermore, the first to the seventh preferred embodiments are carried out at a temperature ranging from about 100° C. to about 650° C. for about 1 minute to about 5 minutes.

As described above, the TiWN 23 is densified and filled with oxygen to make a microstructure of the diffusion barrier layer amorphous. Herein, the diffusion barrier layer does not contain silicon but refractory metal, e.g., W, and nitrogen additionally added to refractory metal, Ti.

Referring to FIG. 3B, after completing the reforming process, a Cu layer is deposited on the inter-layer insulating layer 22 until filling entirely the via hole pattern and the line pattern. A chemical mechanical polishing (CMP) process is continuously applied to the Cu layer and the TiWN 23 until exposing a surface of the inter-layer insulating layer 22. Thereafter, a via 24 and a Cu line 25 are simultaneously formed. As described in FIG. 2, the TiWN 23 is an amorphous tertiary nitride and referred as to amorphous diffusion barrier layer hereinafter.

The amorphous diffusion barrier layer described as the above maintains a chemical bonding of Ti, W and N even at the high thermal process due to their strong chemical affinities. Also, the amorphous diffusion barrier layer is able to retain a low electric resistance since it contains N and refractory metal such as Ti and W of which resistance is low.

As seen from the above, the amorphous diffusion barrier layer containing the refractory metal and N is able to prevent diffusion of Cu evidently occurring at a wiring process even at a high temperature, thereby broadening a range of applicable temperature for the wiring process. Ultimately, it is possible to improve reliability of a semiconductor device.

While the present invention has been described with respect to certain preferred embodiments, it will be apparent to those skilled in the art that various changes and modifications may be made without departing from the scope of the invention as defined in the following claims.

What is claimed is:

1. A method for fabricating a semiconductor device, comprising the steps of:
depositing a tertiary nitride containing titanium (Ti), tungsten (W) and nitrogen (N) on a substrate loaded inside of a reactive deposition chamber; and
densifying the tertiary nitride and performing a reforming process for filling a surface of the tertiary nitride with oxygen.

2. The method as recited in claim 1, wherein the step of depositing the tertiary nitride further includes the steps of:
mounting a Ti target and a W target inside of the reactive deposition chamber;
supplying a mixed gas of argon (Ar) and nitrogen (N₂) gas to the reactive deposition chamber;
forming Ar plasma by ionizing the Ar gas;
setting Ar⁺ ions contained in the Ar plasma to collide with the Ti target and the W target; and
setting Ti+ and W+ ions come off from each surface of the Ti and W targets to react with the N₂ gas.

3. The method as recited in claim 1, wherein the step of depositing the tertiary nitride is performed at a temperature ranging from about 100° C. to about 900° C. until having a thickness of the tertiary nitride ranging from about 200 Å to about 1000 Å.

4. The method as recited in claim 1, wherein each compositional ratio of the Ti, W and N contained in the tertiary nitride ranges from about 50 at % to about 90 at %, from about 10 at % to about 50 at %, and from about 10 at % to about 80 at %.

5. The method as recited in claim 1, wherein the reforming process is carried out inside of the reactive deposition chamber in which the tertiary nitride is deposited or inside of an additional thermal process chamber.

6. A method for fabricating a semiconductor device, comprising the steps of:
forming a conductive layer on top of a substrate;
forming a diffusion barrier layer constructed with titanium (Ti), tungsten (W) and nitrogen (N) on the conductive layer; and
forming a Cu line on the diffusion barrier layer.

7. The method as recited in claim 6, wherein the step of forming the diffusion barrier layer is deposited at a temperature in a range from 100° C. to about 900° C. until having a thickness ranging from about 200 Å to about 1000 Å.

8. The method as recited in claim 6, wherein each compositional ratio of the Ti, W and N contained in the tertiary nitride ranges from about 50 at % to about 90 at %, rom about 10 at % to about 50 at %, and from about 10 at % to about 80 at %.

9. The method as recited in claim 6, wherein the step of forming the conductive layer is followed by further the steps of:
forming an inter-layer insulating layer on the conductive layer; and
etching selectively the inter-layer insulating layer to form a dual damascene pattern that exposes a certain portion of the conductive layer.
